(19) United States
(12) Patent Application Publication
(10) Pub. No.: US 2015/0240344 A1
(43) Pub. Date: Aug. 27, 2015

(54) RUTHENIUM FILM FORMING METHOD, RUTHENIUM FILM FORMING APPARATUS, AND SEMICONDUCTOR DEVICE MANUFACTURING METHOD

(71) Applicant: TOKYO ELECTRON LIMITED, Tokyo (JP)

(72) Inventors: Tadahiro ISHIZAKA, Nirasaki City (JP); Takashi SAKUMA, Nirasaki City (JP); Tatsuo HIRASAWA, Nirasaki City (JP)

(21) Appl. No.: 14/623,398

(22) Filed: Feb. 16, 2015

(30) Foreign Application Priority Data
Feb. 26, 2014 (JP) 2014-035217

(51) Int. Cl. C23C 14/22; H01L 21/768; C23C 14/54

(52) U.S. Cl. CPC C23C 14/22; C23C 14/54; H01L 21/76846; H01L 21/76879; H01L 21/76883; H01L 21/76867

(57) ABSTRACT

A ruthenium film forming method includes: placing a target substrate in a processing container; supplying ruthenium carbonyl gas together with CO gas as a carrier gas into the processing container, the ruthenium carbonyl gas being generated from solid-state ruthenium carbonyl; supplying additional CO gas into the processing container; and forming a ruthenium film on the target substrate by decomposing the ruthenium carbonyl gas.

### CROSS-REFERENCE TO RELATED APPLICATION

This application claims priority to Japanese Patent Application No. 2014-035217, filed on Feb. 26, 2014, in the Japan Patent Office, the disclosure of which is incorporated herein in its entirety by reference.

### TECHNICAL FIELD

The present disclosure relates to a ruthenium film forming method, a ruthenium film forming apparatus and a semiconductor device manufacturing method.

### BACKGROUND

According to demands for high-speed semiconductor devices and miniaturization and high integration of wiring patterns, there has been a need to lower inter-capacitance between wirings and to improve electrical conductivity and electromigration resistance of the wirings. In response to these needs, Cu multilayer wiring technology is attracting attention. In the Cu multilayer wiring technology, copper (Cu), which has higher electrical conductivity and better electromigration resistance than aluminum (Al) or tungsten (W), is used as a wiring material and a low dielectric constant film (low-k film) is used as an interlayer insulating film.

As a method for forming Cu wiring, it is known that a barrier layer including Ta, TaN, Ti or the like is formed on a low-k film where a trench or hole is formed by means of physical vapor deposition (PVD) represented by sputtering, a Cu seed layer is formed on the barrier layer also by means of PVD, and then Cu plating is conducted on the Cu seed layer.

However, since the design rule of semiconductor devices is becoming more miniaturized, in the aforementioned method, it is difficult to form the Cu seed layer in the trench or hole by means of PVD having basically low step coverage whereby the Cu film in the trench or hole is formed to have voids.

In this regard, a method for forming a ruthenium film on a barrier layer by means of chemical vapor deposition (CVD) and then forming a Cu film on the barrier layer has been proposed. The CVD-ruthenium film has better step coverage than the PVD-Cu film and has good adhesivity with a Cu film. Accordingly, the CVD-ruthenium film is effective as a base for burying a Cu film in a minute trench or hole.

As a method for forming the CVD-ruthenium film, it is known that a ruthenium carbonyl (Ru₃(CO)₁₂) is used as a film forming source. In the case of using ruthenium carbonyl, it is possible to obtain a high-purity film because impurity components in the film forming source are carbon and oxygen only.

However, ruthenium carbonyl is easily decomposed at a relatively low temperature. If ruthenium carbonyl is decomposed before reaching a substrate, it is likely that desired step coverage cannot be obtained. In this regard, a technique is known that CO gas, which has an effect of suppressing decomposition of ruthenium carbonyl, is used as a carrier gas.

With semiconductor devices becoming more miniaturized beyond the 22 nm node, it would be necessary to form an extremely thin ruthenium film having a film thickness of equal to or less than 2 nm with extremely high step coverage. Therefore, it is expected that sufficient step coverage will be difficult to obtain using the aforementioned technique.

### SUMMARY

The present disclosure provides a method and apparatus for forming a ruthenium film with better step coverage in comparison with the case using conventional techniques, and a semiconductor device manufacturing method using the ruthenium film.

According to a first aspect of the present disclosure, there is provided a ruthenium film forming method that includes: placing a target substrate in a processing container; supplying ruthenium carbonyl gas together with CO gas as a carrier gas into the processing container, the ruthenium carbonyl gas being generated from solid-state ruthenium carbonyl; supplying additional CO gas into the processing container; and forming a ruthenium film on the target substrate by decomposing the ruthenium carbonyl gas.

According to a second aspect of the present disclosure, there is also provided a ruthenium film forming apparatus that includes: a processing container that accommodates a target substrate; a film forming source container that accommodates solid-state ruthenium carbonyl as a film forming source; a carrier gas supply pipe that supplies CO gas as a carrier gas into the film forming source container; a film forming source gas supply pipe that supplies a ruthenium carbonyl gas together with the CO gas as the carrier gas into the processing container, the ruthenium carbonyl gas being generated from the solid-state ruthenium carbonyl in the film forming source container; and an additional CO gas pipe that supplies additional CO gas into the processing container; wherein a ruthenium film is formed on the target substrate by decomposing the ruthenium carbonyl gas.

According to a third aspect of the present disclosure, there is also provided a semiconductor device manufacturing method that includes: forming a barrier film as a copper diffusion barrier on at least a surface of a concave portion in a substrate, the substrate including an interlayer insulating film and the concave portion being formed in the interlayer insulating film; forming a ruthenium film on the barrier film by the method of the first aspect; and forming a copper film on the ruthenium film by means of physical vapor deposition so that copper as a copper wiring is buried in the concave portion.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a sectional view illustrating an example of a film forming apparatus for performing a ruthenium film forming method according to an embodiment of the present disclosure.

FIG. 2 is SEM images illustrating a relationship between a flow rate of additional counter CO gas and step coverage when forming a ruthenium film.

FIG. 3 is a graph illustrating a relationship between a partial pressure ratio of Ru₃(CO)₁₂/CO when forming the ruthenium film and the number of voids observed after an immersion process using a hydrofluoric acid-based chemical liquid.

FIG. 4 is a flowchart illustrating a Cu wiring forming method (semiconductor device manufacturing method) according to another embodiment of the present disclosure.

FIGS. 5A to 5F are sectional process views for explaining the Cu wiring forming method (semiconductor device manufacturing method) according to another embodiment of the present disclosure.

FIG. 6 is a plan view illustrating an example of a film forming system for use in the Cu wiring forming method according to another embodiment of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the inventive aspects of this disclosure. However, it will be apparent to one of ordinary skill in the art that the inventive aspects of this disclosure may be practiced without these specific details. In other instances, well-known methods, procedures, systems, and components have not been described in detail so as not to unnecessarily obscure aspects of the various embodiments.

As a result of repeated research, the inventors of the present disclosure found out that decomposition of ruthenium carbonyl can be suppressed by using CO gas as a carrier gas of a film forming source, i.e., ruthenium carbonyl, and furthermore supplying additional CO gas into a processing container, whereby a ruthenium film can be formed with good step coverage. The present disclosure was completed based on the result.

### <Ruthenium Film Forming Apparatus>

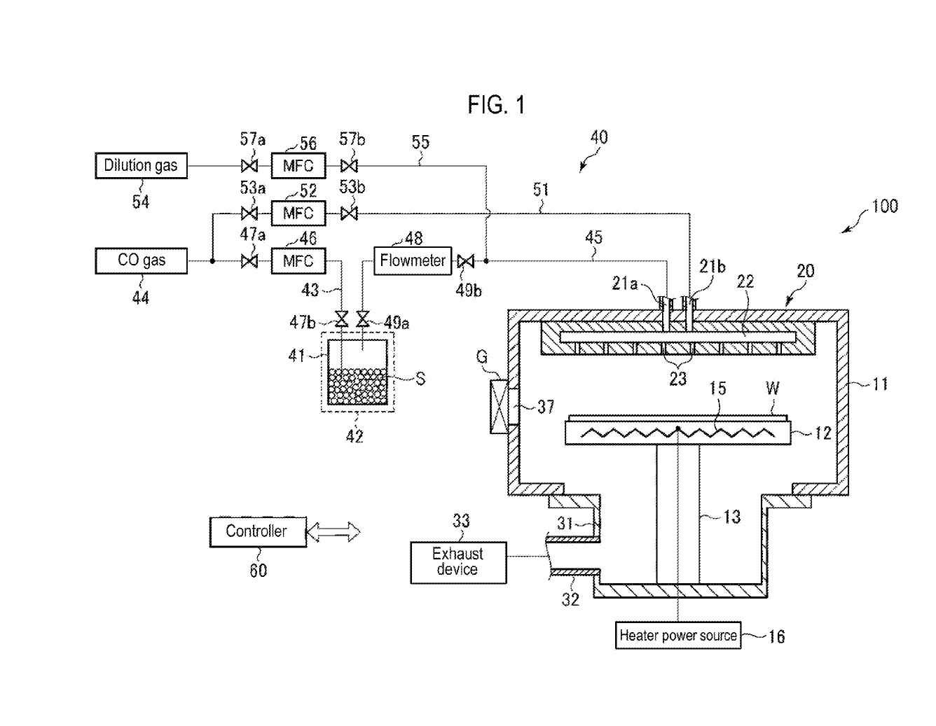

FIG. 1 is a sectional view illustrating an example of a film forming apparatus for performing a ruthenium film forming method according to an embodiment of the present disclosure.

A ruthenium film forming apparatus 100 forms a ruthenium film (hereinafter, also referred to as “Ru film”) by means of CVD. The ruthenium film forming apparatus 100 includes a substantially cylindrical chamber 11 which is airtightly sealed. In the chamber 11, a susceptor 12 for horizontally holding a wafer W as a target substrate is arranged. The susceptor 12 is supported by a cylindrical supporting member 13 installed at the center of a bottom wall of the chamber 11. A heater 15 is embedded in the susceptor 12 and is connected to a heater power source 16. The heater power source 16 is controlled by a heater controller (not shown) based on a detection signal of a thermocouple (not shown) installed in the susceptor 12, whereby the wafer W is controlled to be a desired temperature through the susceptor 12. In the susceptor 12, three wafer elevating pins (not shown) that vertically moves the wafer W supported thereon are installed such that the wafer elevating pins can project and retract with respect to the surface of the susceptor 12.

In a ceiling wall of the chamber 11, a shower head 20 that introduces a processing gas, which is used for forming a Ru film by means of CVD, to the inside of the chamber 11 in a shower form is installed to face the susceptor 12. The shower head 20 injects a gas supplied from a gas supply mechanism 40 (to be described later) to the inside of the chamber 11. Two gas inlets 21a and 21b that introduce a gas are formed in the upper portion of the shower head 20, and a gas diffusion space 22 is formed in the shower head 20. A plurality of gas injection holes 23 communicating with the gas diffusion space 22 is formed in the bottom surface of the shower head 20.

In the bottom wall of the chamber 11, an exhaust chamber 31 is installed to protrude downward. An exhaust pipe 32 is connected to the side surface of the exhaust chamber 31. The exhaust pipe 32 is connected to an exhaust device 33 having a vacuum pump, a pressure control valve and so forth. The inside of the chamber 11 can be set to be a predetermined depressurized state (vacuum state) by operating the exhaust device 33.

In the side wall of the chamber 11, a loading/unloading gate 37 is installed to load and unload the wafer W between the chamber 11 and a transfer chamber (not shown) under a predetermined depressurized state. The loading/unloading gate 37 is opened and closed by a gate valve G.

The gas supply mechanism 40 includes a film forming source container 41 accommodating ruthenium carbonyl (Ru₃(CO)₁₂) as a solid-state film forming source S. The film forming source container 41 is surrounded by a heater 42. A carrier gas supply pipe 43 that supplies CO gas as a carrier gas is inserted into the film forming source container 41 from above. The carrier gas supply pipe 43 is connected to a CO gas supply source 44 that supplies a CO gas. A film forming source gas supply pipe 45 is also inserted into the film forming source container 41. The film forming source gas supply pipe 45 is connected to the gas inlet 21a of the shower head 20. Therefore, CO gas as a carrier gas is blown from the CO gas supply source 44 to the inside of the film forming source container 41 through the carrier gas supply pipe 43, and ruthenium carbonyl (Ru₃(CO)₁₂) gas vaporized in the film forming source container 41 is carried by the CO gas and supplied to the inside of the chamber 11 through the film forming source gas supply pipe 45 and the shower head 20. In the carrier gas supply pipe 43, a mass flow controller 46 that controls a flow rate of the carrier gas and valves 47a and 47b provided at the upstream and downstream of the mass flow controller 46, respectively, are installed. In the film forming source gas supply pipe 45, a flowmeter 48 that detects a flow rate of the ruthenium carbonyl (Ru₃(CO)₁₂) gas and valves 49a and 49b provided at the upstream and downstream of the flowmeter 48, respectively, are installed.

The gas supply mechanism 40 also includes a counter CO gas pipe 51 branched at the upstream of the valve 47a in the carrier gas supply pipe 43. The counter CO gas pipe is connected to the gas inlet 21b of the shower head 20. Therefore, in addition to the ruthenium carbonyl gas, the CO gas from the CO gas supply source 44 is supplied to the inside of the chamber 11, as an additional counter CO gas, through the counter CO gas pipe 51 and the shower head 20. In the counter CO gas pipe 51, a mass flow controller 52 that controls a flow rate of the CO gas and the valves 53a and 53b provided at the upstream and downstream of the mass flow controller 52, respectively, are installed.

The gas supply mechanism 40 also includes a dilution gas supply source 54 and a dilution gas supply pipe 55 having an end portion connected to the dilution gas supply source 54. The other end portion of the dilution gas supply pipe 55 is connected to the film forming source gas supply pipe 45. The dilution gas serves as a gas for diluting the film forming source gas. An inert gas such as Ar gas or N₂ gas is used as the dilution gas. The dilution gas also serves as a purge gas for purging residual gases within the film forming source gas supply pipe 45 and the chamber 11. In the dilution gas supply pipe 55, a mass flow controller 56 that controls a flow rate of the dilution gas and valves 57a and 57b provided at the upstream and downstream of the mass flow controller 56, respectively, are installed.

The ruthenium film forming apparatus 100 includes a controller 60 that controls each component such as the heater power source 16, the exhaust device 33, the gas supply mechanism 40 or the like. The controller 60 controls each component according to a command of a higher level control device. The higher level control device includes a non-transitory storage medium which stores processing recipes for performing the below-described film forming method, and controls the film forming processing according to the processing recipes stored in the non-transitory storage medium.

### <Ruthenium Film Forming Method>

Hereinafter, a ruthenium film forming method using the aforementioned ruthenium film forming apparatus 100 will be explained.

First, the gate valve G is opened to load the wafer W into the chamber 11 through the loading/unloading gate 37, and then the wafer is placed on the susceptor 12. The wafer W is heated on the susceptor 12 which is heated by the heater 15 to a temperature of, for example, 150 to 250 degrees C. The inside of the chamber 11 is vacuum-exhausted by the vacuum pump in the exhaust device 33 to a pressure of 2 to 67 Pa.

Next, the valves 47a and 47b are opened to blow CO gas as a carrier gas into the film forming source container 41 through the carrier gas supply pipe 43. In the film forming source container 41, the solid-state film forming source S is heated by the heater 42 to produce Ru₃(CO)₁₂ gas by sublimation. The Ru₃(CO)₁₂ gas is carried by the CO gas and introduced into the chamber 11 through the film forming source gas supply pipe 45 and the shower head 20. On the surface of the wafer W, ruthenium (Ru) produced by thermal decomposition of the Ru₃(CO)₁₂ gas is deposited to form a ruthenium film with a predetermined thickness. In some embodiments, the flow rate of the CO gas as a carrier gas may be, for example, 300 mL/min (sccm) or below so that the flow rate of the Ru₃(CO)₁₂ gas becomes, for example, 5 mL/min (sccm) or below. Also, a dilution gas may be introduced into the chamber 11 at a predetermined ratio.

By using the CO gas as a carrier gas as described above, decomposition reaction of Ru₃(CO)₁₂ gas described below as formula (1) may be suppressed, and thus the film forming source gas can be supplied to the inside of the chamber 11 while maintaining the structure of Ru₃(CO)₁₂ as much as possible.

Ru₃(CO)₁₂→3Ru+12CO (1)

In the surface of the wafer W placed in the chamber 11, absorption/desorption reaction of Ru₃(CO)₁₂ and CO described below as formula 2 occurs. This reaction is a surface reaction limit which allows a good step coverage when forming a film in a concave portion such as a trench or hole. The absorption/desorption reaction of Ru₃(CO)₁₂ and CO is considered as an equilibrium reaction.

Ru₃(CO)₁₂(g)←→Ruₓ(CO)_{y}(ad)+(12-y)CO(ad)←→3Ru(s)+12CO(g) (2)

Although good step coverage can be obtained by the above surface reaction limit, when considering Cu wirings in more miniaturized upcoming semiconductor devices beyond the 22 nm node, it gets difficult to form a Ru film, which has an extremely thin film thickness of 2 nm or below, as a base of a Cu film with a desired step coverage. As the semiconductor devices become more miniaturized, a concave portion such as a trench or hole is decreased in width and increased in aspect ratio. For that reason, it is necessary to suppress decomposition of Ru₃(CO)₁₂ to make the Ru₃(CO)₁₂ reach the bottom portion of the fine trench or hole, which is, however, difficult with conventional techniques.

After reviewing methods for suppressing decomposition of Ru₃(CO)₁₂, it was found that decreasing a partial pressure ratio of Ru₃(CO)₁₂/CO by increasing a partial pressure of CO is effective. In other words, by increasing the partial pressure of CO, the backward reaction in the aforementioned formula 2 becomes more predominant and decomposition of Ru₃(CO)₁₂ can be suppressed.

However, in a case of only increasing the supply of CO gas as a career gas in order to increase the partial pressure of CO, the flow rate of Ru₃(CO)₁₂ is also increased. Therefore, it is difficult to sufficiently decrease the partial pressure ratio of Ru₃(CO)₁₂/CO.

For that reason, in the present embodiment, the counter CO gas pipe 51 is installed to supply, in addition to the CO gas as a carrier gas, the counter CO gas to the inside of the chamber 11. By introducing, in addition to the ruthenium carbonyl gas, the additional counter CO gas to the inside of the chamber 11 through the counter CO gas pipe 51 and the shower head 20, the partial pressure ratio of Ru₃(CO)₁₂/CO is decreased. The Ru film is formed under this state.

Without installing the counter CO gas pipe 51, the lower limit of the partial pressure ratio of Ru₃(CO)₁₂/CO is 0.0028. However, by supplying the counter CO gas through the counter CO gas pipe 51, the lower partial pressure ratio of Ru₃(CO)₁₂/CO can be obtained. In some embodiments, the partial pressure ratio of Ru₃(CO)₁₂/CO may be 0.0025 or lower.

Further, in some embodiments, the flow rate of the CO gas as a carrier gas may be 300 mL/min (sccm) or lower. The flow rate of the CO gas supplied from the counter CO gas pipe 51 may be 100 mL/min (sccm) or above in some embodiments, and may be 100 to 300 mL/min (sccm) in some other embodiments.

When the Ru film with a desired thickness is formed, the valves 47a and 47b are closed to stop the Ru₃(CO)₁₂ gas supply. Further, the valves 53a and 53b are closed to stop the counter CO gas supply, and the dilution gas as a purge gas is introduced from the dilution gas supply source 54 to the inside of the chamber 11 to purge the Ru₃(CO)₁₂ gas. After that, the gate valve G is opened and the wafer W is unloaded from the loading/unloading gate 37.

In practice, a relationship between the flow rate of the counter CO gas (the partial pressure ratio of Ru₃(CO)₁₂/CO) during the Ru film formation and the step coverage was investigated. In the investigation, a TiN film having a thickness of 10 nm was formed in a trench, which has a width of 35 nm and is formed in a SiO₂ film (TEOS film) formed on a wafer, by means of ionized physical vapor deposition (iPVD), and then Ru₃(C 0)₁₂ gas was supplied with a carrier CO gas having a flow rate of 200 mL/min (sccm). Simultaneously, under a pressure of 13.3 Pa and a susceptor temperature of 200 degrees C., Ru films having a thickness of 1.5 nm were formed on the TiN film while changing the flow rate of a counter CO gas in three stages, i.e., 0 mL/min (sccm), 100 mL/min (sccm) and 200 mL/min (sccm), thereby manufacturing samples A to C, respectively. The samples A to C were subjected to a treatment using hydrofluoric acid-based chemical liquid, and then step coverage was evaluated. Specifically, the samples A to C were immersed in a BHF liquid (a mixed solution of a HF aqueous solution and a NH₄F aqueous solution) as a hydrofluoric acid-based chemical liquid for three minutes, and then the step coverage was evaluated by counting the number of voids in each sample by means of scanning electron microscope (SEM) observation. Since a TiN film as a base of the Ru film is dissolved in a hydrofluoric acid-based chemical liquid, portions in the TiN film where the Ru film was not normally deposited were dissolved to form voids. Therefore, continuity of the Ru film could be evaluated.

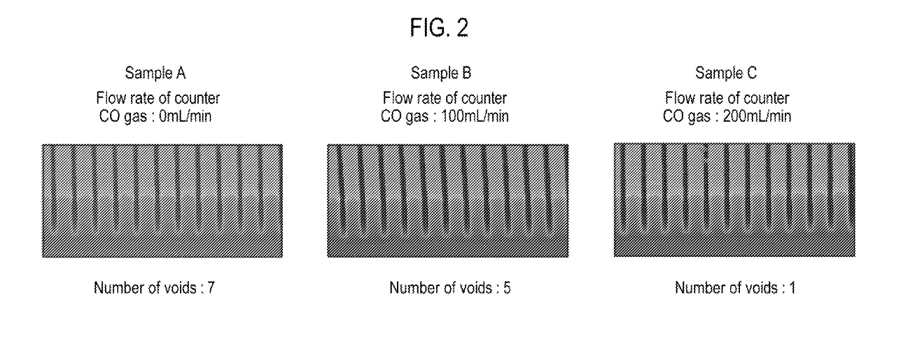

SEM images of the samples A to C are illustrated in FIG. 2. As a result of counting the number of voids in the visual field of the SEM images in FIG. 2, seven voids were found in the sample A where the flow rate of the counter CO gas is 0 mL/min (sccm), five voids were found in the sample B where the flow rate of the counter CO gas is 100 mL/min (sccm), and one void was found in the sample C where the flow rate of the counter CO gas is 200 mL/min (sccm). That is to say, it was confirmed that as the flow rate of the counter CO gas increases, i.e., as the partial pressure ratio of Ru₃(CO)₁₂/CO decreases, a better continuity of Ru film and a higher step coverage are obtained. The partial pressure ratios of Ru₃(CO)₁₂/CO calculated from the gas flow rates in the samples A, B and C were 0.0028, 0.0018 and 0.0014, respectively.

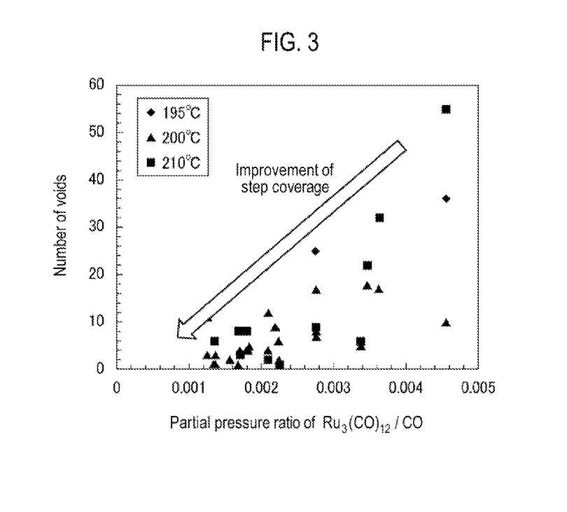

Further, an experiment was conducted while varying the susceptor temperature and the flow rates of the carrier CO gas and counter CO gas, and FIG. 3 illustrates the relation between the partial pressure ratio of Ru₃(CO)₁₂/CO and the number of voids. It is clearly shown in FIG. 3 that the number of voids decreases as the partial pressure ratio of Ru₃(CO)₁₂/CO decreases (correlation coefficient is 0.73). It was also confirmed that the step coverage is improved by decreasing the partial pressure ratio of Ru₃(CO)₁₂/CO.

### <Cu Wiring Forming Method>

Next, as another embodiment of the present disclosure, a Cu wiring forming method (a semiconductor device manufacturing method) using the Ru film formed as described above will be explained below.

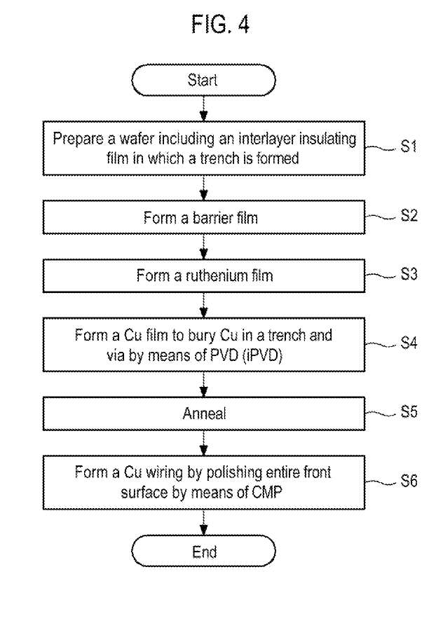

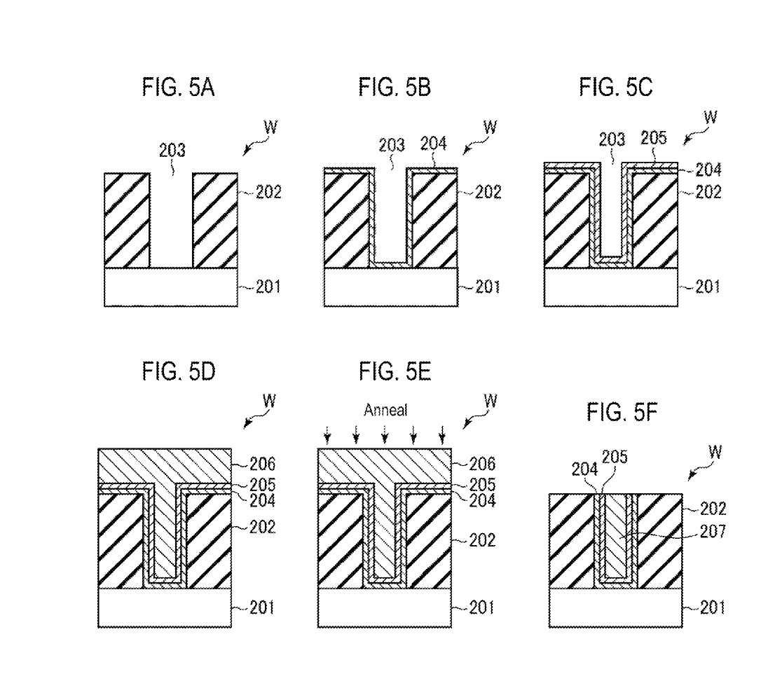

FIG. 4 is a flowchart illustrating a Cu wiring forming method. FIGS. 5A to 5F are sectional process views of the Cu wiring forming method.

First, a semiconductor wafer (hereinafter simply referred to as “wafer”) W is prepared. The wafer W includes an interlayer insulating film 202, e.g., a SiO₂ film, a low-k film (SiCO, SiCOH or the like) or the like, formed “on a base structure 201 (details thereof are omitted) and a trench 203 and via (not shown) for connection to an underlayer wiring formed in the interlayer insulating film 202 in a desired pattern (step S1, FIG. 5A). In some embodiments, moisture or etching/ashing residue on the surface of the interlayer insulating film 202 in the wafer W may be removed by a degas process or a pre-clean process.

Next, a barrier film 204 that suppress diffusion of Cu is formed on the entire surface of the interlayer insulating film 202 including surfaces of the trench 203 and the via (step S2, FIG. 5B).

In some embodiments, the barrier film 204 may have high barrier properties against Cu and a low resistance. A Ti film, TiN film, Ta film, TaN film or Ta/TaN double layered film may be appropriately used as the barrier film 204. Alternatively, a TaCN film, W film, WN film, WCN film, Zr film, ZrN film, V film, VN film, Nb film, NbN film or the like may also be used as the barrier film 204. The resistance of Cu wirings decreases as the volume of Cu buried in the trench or hole increases. Therefore, in some embodiments, the barrier film 204 may be formed to be extremely thin From this point of view, the thickness of the barrier film 204 may be 1 to 20 nm in some embodiments, and 1 to 10 nm in some other embodiments. The barrier film 204 may be formed by means of iPVD (ionized physical vapor deposition), for example, plasma sputtering. The barrier film 204 may also be formed by means of other PVD methods such as ordinary sputtering, ion plating or the like, or by means of CVD, ALD, plasma CVD or plasma ALD.

Next, a Ru film 205 as a liner film is formed on the bather film 204 by means of the aforementioned CVD using ruthenium carbonyl (Ru₃(CO)₁₂) (step S3, FIG. 5C). In order to increase the volume of buried Cu to lower the resistance of the Cu wirings, in some embodiments, the Ru film may be formed to be thin, for example, 1 to 5 nm in thickness.

Ru has a high wettability against Cu. For that reason, by forming a Ru film as a base of Cu, good Cu mobility during the subsequent Cu film formation by means of iPVD can be secured, which suppresses generation of an overhang that may block the trench or hole. Further as described above, by supplying the counter CO gas and decreasing the partial pressure ratio of Ru₃(CO)₁₂/CO, good step coverage can be obtained. For these reasons, it is possible to certainly bury Cu in more miniaturized future trenches or holes without generating voids.

Subsequently, a Cu film 206 is formed by means of PVD to bury Cu in the trench 203 and via (not shown) (step S4, FIG. 5D). In some embodiments, iPVD may be used as PVD, whereby generation of Cu overhangs can be suppressed and good buriability can be obtained. Moreover, a Cu film formed by means of PVD may have higher purity than a copper film formed by means of plating. In some embodiments, in preparation for a planarization process to be performed after the Cu film formation, the Cu film 206 may be further deposited to form an increased portion from the top surface of the trench 203. In this case, the increased portion of the Cu film 206 may be formed by means of plating, instead of being formed by further performing PVD.

After forming the Cu film 206, an annealing process is performed if necessary (step S5, FIG. 5E). The annealing process stabilizes the Cu film 206.

Thereafter, the entire front surface of the wafer W is polished by means of CMP (Chemical Mechanical Polishing), whereby the Cu film 206 formed on the front surface of the wafer W and the Ru film 205 and the bather film 204 disposed below the Cu film 206 are removed for planarization (step S6, FIG. 5F). In this way, a Cu wiring 207 is formed in the trench and via (hole).

After forming the Cu wiring 207, an appropriate cap film such as a dielectric cap, a metal cap or the like is formed on the entire front surface of the wafer W including the Cu wiring 207 and the interlayer insulating film 202.

By using the aforementioned method, the Ru film can be formed in the fine trenches or holes with high step coverage, whereby the Cu film can be buried without generating voids. Since the Ru film can be formed with high step coverage, the Ru film can be formed to be extremely thin and the volume of Cu in the Cu wirings can be increased more, whereby the resistance Cu wirings can be lowered. Further, the crystal grain of Cu can be increased by burying Cu by means of PVD, whereby the resistance Cu wirings can be lowered.

### <Film Forming System for Forming Cu Wirings>

Next, a film forming system suitable for performing the Cu wiring forming method according to the another embodiment of the present disclosure is explained below.

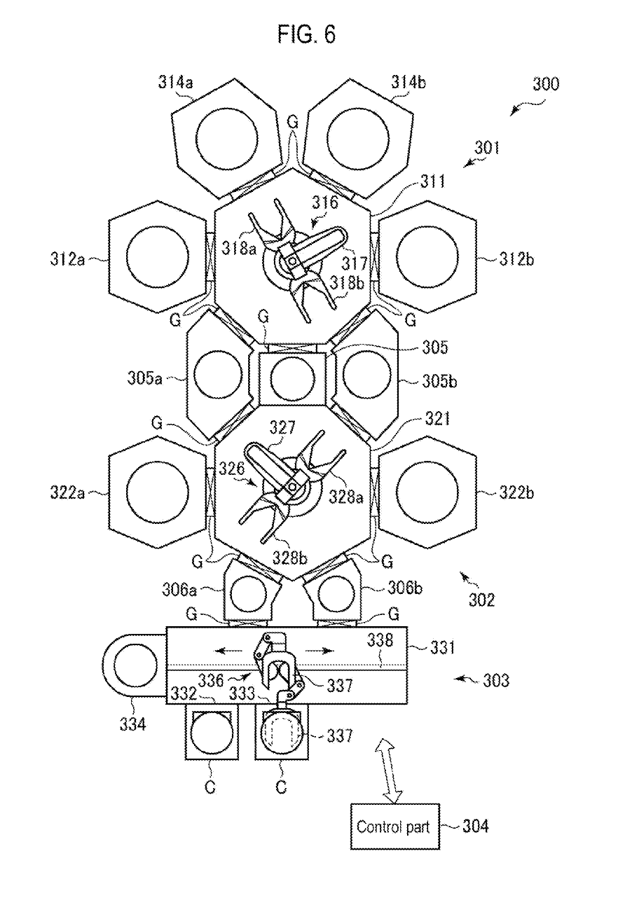

FIG. 6 is a plan view illustrating an example of a film forming system for use in the Cu wiring forming method according to another embodiment of the present disclosure.

A film forming system 300 forms a Cu wiring in a wafer W by performing base film formation and Cu film formation. The film forming system 300 includes a first processing part 301 that forms a barrier film and a Ru film, a second processing part 302 that forms a Cu film, a loading/unloading part 303, and a control part 304.

The first processing part 301 includes a first vacuum transfer chamber 311, two barrier film forming apparatuses 312a and 312b and two Ru film forming apparatuses 314a and 314b. The barrier film forming apparatuses 312a and 312b and the Ru film forming apparatuses 314a and 314b are connected to wall portions of the first vacuum transfer chamber 311. The Ru film forming apparatuses 314a and 314b have the same configuration as that of the aforementioned ruthenium film forming apparatus 100. The location of the barrier film forming apparatus 312a and the Ru film forming apparatus 314a is in line-symmetric with the location of the barrier film forming apparatus 312b and the Ru film forming apparatus 314b.

Degas chambers 305a and 305b that perform a degas process on the wafer W are connected to other wall portions of the first vacuum transfer chamber 311. In addition, a transfer chamber 305 that transfers the wafer W between the first vacuum transfer chamber 311 and a second vacuum transfer chamber 321 to be described later is connected to the wall portion of the first vacuum transfer chamber 311 disposed between the degas chambers 305a and 305b.

Each of the barrier film forming apparatuses 312a and 312b, the Ru film forming apparatuses 314a and 314b, the degas chambers 305a and 305b, and the transfer chamber 305 is connected to a corresponding side wall portion of the first vacuum transfer chamber 311 with a gate valve G interposed therebetween, and is communication with and blocked from the first vacuum transfer chamber 311 by opening and closing a corresponding gate valve G.

The inside of the first vacuum transfer chamber 311 is kept to be a predetermined vacuum atmosphere, and a first transfer mechanism 316 that transfers the wafer W is installed inside of the first vacuum transfer chamber 311. The first transfer mechanism 316 is arranged in an approximate center of the first vacuum transfer chamber 311. The first transfer mechanism 316 includes a rotatable and extensible/contractible part 317 and two support arms 318a and 318b that support the wafer W. The support arms 318a and 318b are installed at the leading end of the rotatable and extensible/contractible part 317. The first transfer mechanism 316 transfers the wafer W to and from the barrier film forming apparatuses 312a and 312b, the Ru film forming apparatuses 314a and 314b, the degas chambers 305a and 305b, and the transfer chamber 305.

The second processing part 302 includes the second vacuum transfer chamber 321 and two Cu film forming apparatuses 322a and 322b connected to wall portions of the second vacuum chamber 321 facing each other. The Cu film forming apparatuses 322a and 322b may be used as an apparatuses that performs all the processes from a concave portion burying process to a film forming process for forming the increased portion. Alternatively, the Cu film forming apparatuses 322a and 322b may be used for the concave portion burying process only and the increased portion may be formed by plating.

The degas chambers 305a and 305b are connected to two wall portions of the second vacuum transfer chamber 321 disposed at the side of the first processing part 301. The transfer chamber 305 is connected to a wall portion of the second vacuum transfer chamber 321 disposed between the degas chambers 305a and 305b. That is to say, the transfer chamber 305 and the degas chambers 305a and 305b are all installed between the first vacuum transfer chamber 311 and the second vacuum transfer chamber 321, and the degas chambers 305a and 305b are arranged in right and left sides of the transfer chamber 305. In addition, load lock chambers 306a and 306b, each of which is capable of performing atmospheric transfer and vacuum transfer, are connected to two wall portions of the second vacuum transfer chamber 321 disposed at the side of the loading/unloading part 303.

Each of the Cu film forming apparatuses 322a and 322b, the degas chambers 305a and 305b, and the load lock chambers 306a and 306b is connected to a corresponding wall portion of the second vacuum transfer chamber 321 with a gate valve G interposed therebetween. Each of the Cu film forming apparatuses 322a and 322b, the degas chambers 305a and 305b, and the load lock chambers 306a and 306b is communicated with the second vacuum transfer chamber 321 by opening a corresponding gate valve G, and is blocked from the second vacuum transfer chamber 321 by closing the corresponding gate valve G. The transfer chamber 305 is connected to the second vacuum transfer chamber 321 without a gate valve interposed therebetween.

The inside of the second vacuum transfer chamber 321 is kept to be a predetermined vacuum atmosphere, and a second transfer mechanism 326 is installed inside of the second vacuum transfer chamber 321. The second transfer mechanism 326 loads and unloads the wafer W to and from the Cu film forming apparatuses 322a and 322b, the degas chambers 305a and 305b, the load lock chambers 306a and 306b and the transfer chamber 305. The second transfer mechanism 326 is arranged in an approximate center of the second vacuum transfer chamber 321. The second transfer mechanism 326 includes a rotatable and extensible/contractible part 327 and two support arms 328a and 328b that support the wafer W. The support arms 328a and 328b are installed at the leading end of the rotatable and extensible/contractible part 327. The two support arms 328a and 328b are installed in the rotatable and extensible/contractible part 327 to face opposite directions from each other.

The loading/unloading part 303 is installed at the opposite side of the second processing part 302 with the load lock chambers 306a and 306b interposed therebetween, and includes an air transfer chamber 331 to which the load lock chambers 306a and 306b are connected. In the upper portion of the air transfer chamber 331, a filter (not shown) is installed to form a down flow of fresh air. Gate valves G are installed in a wall portion of the air transfer chamber 331 to which the load lock chambers 306a and 306b are connected. Two connection ports 332 and 333, to which carriers C accommodating the wafers W as target substrates are connected, are installed in a wall portion of the air transfer chamber 331 opposing the wall portion to which the load lock chamber 306a and 306b are connected. An alignment chamber 334 that performs alignment of the wafer W is installed in a side wall portion of the air transfer chamber 331. An air transfer mechanism 336 is installed in the air transfer chamber 331. The air transfer mechanism 336 loads and unloads the wafer W to and from the carriers C and the load lock chambers 306a and 306b. The air transfer mechanism 336 includes two multi-joint arms, and can move along a rail 338 in the arrangement direction of the carriers C. The air transfer mechanism 336 performs wafer transfer with the wafer W held on a hand 337 installed at the leading end of each of the multi-joint arms.

The control part 304 controls respective components of the film forming system 300, for example, the barrier film forming apparatuses 312a and 312b, the Ru film forming apparatuses 314a and 314b, the Cu film forming apparatuses 322a and 322b, and the transfer mechanisms 316, 326 and 336. The control part 304 functions as a higher level control device of controllers (not shown), e.g., the controller 60, that control the respective components independently. The control part 304 includes a process controller, a user interface, and a storage unit. The process controller consists of a microprocessor (computer) for executing control of the respective components. The user interface includes a keyboard, through which an operator inputs commands for controlling the film forming system 300, and a display that visualizes and shows operation status of the film forming system 300. The storage unit stores a control program for executing processes to be performed in the film forming system 300 under a control of the process controller, and a program, i.e., processing recipes, for executing processes in the respective components of the film forming system 300 according to various data and processing conditions. The user interface and the storage unit are connected to the process controller.

The processing recipes are stored in a non-transitory storage medium of the storage unit. The non-transitory storage medium may be a hard disk or a mobile storage medium such as CD-ROM, DVD, flash memory or the like. The recipes may be transmitted from other devices, for example, through a dedicated line.

If necessary, an arbitrary recipe is retrieved from the storage unit according to a command received from the user interface and is executed on the process controller, whereby a desired process is performed in the film forming system 300 under a control of the process controller.

In the film forming system 300, the wafer W, in which a predetermined pattern including a trench or hole is formed, is taken out from the carrier C and is transferred to the load lock chamber 306a or 306b by the air transfer mechanism 336. The load lock chamber 306a or 306b is depressurized to a degree of vacuum substantially equal to that of the second vacuum transfer chamber 321. Then, the wafer Win the load lock chamber 306a or 306b is transferred to the degas chamber 305a or 305b through the second vacuum transfer chamber 321 by the second transfer mechanism 326, and is subjected to a degas process. Subsequently, the wafer W is taken out from the degas chamber 305a or 305b and is transferred to the barrier film forming apparatus 312a or 312b through the first vacuum transfer chamber 311 by the first transfer mechanism 316. Then, a barrier film is formed on the wafer W. After forming the barrier film, the wafer W is taken out from the barrier film forming apparatus 312a or 312b and is transferred to the Ru film forming apparatus 314a or 314b by the first transfer mechanism 316. Then, a Ru film is formed on the wafer W as described above. After forming the Ru film, the wafer W is taken out from the Ru film forming apparatus 314a or 314b and is transferred to the transfer chamber 305 by the first transfer mechanism 316. After that, the wafer W is taken out from the transfer chamber 305 and is transferred to the Cu film forming apparatus 322a or 322b through the second vacuum transfer chamber 321 by the second transfer mechanism 326. Then, a Cu film is formed on the wafer W to bury Cu in the trench and via. At this time, in addition to the burying process of Cu, the increased portion of the Cu film may be also formed in the Cu film forming apparatus 322a or 322b. Alternatively, only the burying process of Cu may be performed in the Cu film forming apparatus 322a or 322b, and the increased portion of the Cu film may be formed by plating.

After forming the Cu film, the wafer W is transferred to the load lock chamber 306a or 306b, and the load lock chamber 306a or 306b is restored to atmospheric pressure. Then, the wafer W in which the Cu film is formed is taken out from the load lock chamber 306a or 306b and is transferred to the carrier C by the air transfer mechanism 336. The process described above is repeated by a number of times equal to the number of the wafers W in the carrier C.

According to the film forming system 300, since the nitrogen plasma processing, the Ru film formation, and the Cu film formation can be carried out in a vacuum without being exposed to atmosphere, oxidization on the surfaces after each process can be prevented. Therefore, high-performance Cu wirings can be obtained.

The processes from the barrier film formation to the Cu film formation according to the aforementioned embodiment can be carried out by the film forming system 300. However, the annealing process and the CMP process, which are carried out after the Cu film formation, may be performed on the wafer W taken out from the film forming system 300 by using additional devices. The additional devices may have commonly-used configurations. By constituting a Cu wiring forming system with the additional devices and the film forming system 300 and by controlling the additional devices and the film forming system 300 using a common control unit having the same functions as those of the control part 304, all the processes of the Cu wiring forming method according to the aforementioned embodiment may be controlled by a single processing recipe.

### <Other Applications>

While certain embodiments have been described, this embodiment is not intended to limit the scope of the disclosures. Indeed, the embodiment described herein may be embodied in a variety of other forms. For example, this embodiment shows a case that the Ru film formed according to the present disclosure is used as a base film of the Cu film when forming Cu wirings. However, the present disclosure is not limited to this case. Also, the configurations of the devices have been presented by way of example only, and a variety of configurations of devices may be used.

While the aforementioned embodiments show an example that the methods of the present disclosure is applied to the wafer having the trench and via (hole), the shape of the concave portion is not limited to having both of a trench and via. Also, the structure of the applied device is not limited to the aforementioned embodiments. The substrate is also not limited to a semiconductor wafer.

According to the present disclosure, the ruthenium film is formed by supplying additional CO gas to the processing container while using CO as a carrier gas that carries the ruthenium carbonyl gas as a film forming source. Therefore, it is possible to form the ruthenium film with better step coverage in comparison with the conventional method.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A ruthenium film forming method, comprising:
placing a target substrate in a processing container;
supplying ruthenium carbonyl gas together with CO gas as a carrier gas into the processing container, the ruthenium carbonyl gas being generated from solid-state ruthenium carbonyl;
supplying additional CO gas into the processing container; and
forming a ruthenium film on the target substrate by decomposing the ruthenium carbonyl gas.

2. The ruthenium film forming method of claim 1, wherein a partial pressure ratio of ruthenium carbonyl to CO in the processing container is equal to or less than 0.0025.

3. The ruthenium film forming method of claim 1, wherein a flow rate of the CO gas as the carrier gas is equal to or less than 300 mL/min and a flow rate of the additional CO gas is equal to or more than 100 mL/min.

4. The ruthenium film forming method of claim 1, wherein the ruthenium film is formed on the target substrate having a fine concave portion.

5. A ruthenium film forming apparatus, comprising:
a processing container that accommodates a target substrate;
a film forming source container that accommodates solid-state ruthenium carbonyl as a film forming source;
a carrier gas supply pipe that supplies CO gas as a carrier gas into the film forming source container;
a film forming source gas supply pipe that supplies a ruthenium carbonyl gas together with the CO gas as the carrier gas into the processing container, the ruthenium carbonyl gas being generated from the solid-state ruthenium carbonyl in the film forming source container; and
an additional CO gas pipe that supplies additional CO gas into the processing container;
wherein a ruthenium film is formed on the target substrate by decomposing the ruthenium carbonyl gas.

6. The ruthenium film forming apparatus of claim 5, further comprising:
a controller that controls a partial pressure ratio of ruthenium carbonyl to CO in the processing container to be equal to or less than 0.0025.

7. The ruthenium film forming apparatus of claim 6, wherein the controller controls a flow rate of the CO gas as the carrier gas to be equal to or less than 300 mL/min and controls a flow rate of the additional CO gas to be equal to or more than 100 mL/min.

8. A semiconductor device manufacturing method, comprising:
forming a barrier film as a copper diffusion barrier on at least a surface of a concave portion in a substrate, the substrate including an interlayer insulating film and the concave portion being formed in the interlayer insulating film;
forming a ruthenium film on the barrier film by the method of claim 1; and
forming a copper film on the ruthenium film by means of physical vapor deposition so that copper as a copper wiring is buried in the concave portion.

9. The semiconductor device manufacturing method of claim 8, wherein forming a copper film is performed by means of ionized physical vapor deposition.

10. The semiconductor device manufacturing method of claim 8, further comprising:
after forming the copper film, obtaining the copper wiring by removing the barrier film, the ruthenium film and the copper film, which are formed on portions other than the concave portion, by means of chemical mechanical polishing.
